(19) United States
(12) Patent Application Publication
(10) Pub. No.: US 2026/0052812 A1
(43) Pub. Date: Feb. 19, 2026

(54) LIGHT EMITTING APPARATUS

(71) Applicant: SEOUL SEMICONDUCTOR CO., LTD., Ansan-si (KR)

(72) Inventor: MyungJin KIM, Ansan-si (KR)

(21) Appl. No.: 19/286,991

(22) Filed: Jul. 31, 2025

Related U.S. Application Data
(60) Provisional application No. 63/684,791, filed on Aug. 19, 2024.

(51) Int. Cl. H10H 20/854; H10H 20/851

(52) U.S. Cl. CPC H10H 20/854; H10H 20/8514

(57) ABSTRACT

There may be provided a light emitting apparatus to include a base; a first side wall disposed on the base; and a first light emitting device disposed on the base and configured to generate light, wherein the first side wall includes a plurality of side wall fillers configured to reflect or refract light, and wherein the plurality of side wall fillers includes at least one hollow filler including an air pocket.

### PRIORITY CLAIM AND CROSS-REFERENCE TO RELATED APPLICATIONS

This application claims priority to and the benefit of U.S. Provisional Application No. 63/684,791, filed on Aug. 19, 2024. The aforementioned application of which is incorporated herein by reference in its entirety.

### TECHNICAL FIELD

Various implementations of the disclosed technology relate to a light emitting apparatus.

### BACKGROUND

Recently, a light emitting diode (LED: light emitting diode) is being widely used. The light emitting diode converts an electrical signal into a form of light, such as infrared light, visible light, or ultraviolet light, by using the properties of a compound semiconductor.

As the light efficiency of the light emitting diode increases, a light emitting apparatus is being applied to various fields including a display apparatus, a lighting apparatus, and a lamp for a vehicle.

Recently, there has been a growing demand for a light emitting apparatus that improves cross talk by reducing optical interference from other nearby light emitting apparatuses in order to enhance resolution.

### SUMMARY

Some embodiments of the disclosed technology are directed to providing a light emitting apparatus capable of efficiently refracting light.

Some embodiments of the disclosed technology may provide a light emitting apparatus having a stable structure without damage such as cracks even under heat generation or thermal stress.

Some embodiments of the disclosed technology may provide a light emitting apparatus in which contrast is improved by minimizing optical interference between light emitting units.

Some embodiments of the disclosed technology may provide a light emitting apparatus in which luminance is improved by adjusting the refraction direction.

Some embodiments of the disclosed technology may provide a light emitting apparatus having high illuminance by increasing extraction efficiency.

In accordance with one aspect of the disclosed technology, there may be provided a light emitting apparatus, including: a base; a first side wall disposed on the base; and a first light emitting device disposed on the base and configured to generate light, wherein the first side wall includes a plurality of side wall fillers configured to reflect or refract light, and wherein the plurality of side wall fillers includes at least one hollow filler including an air pocket.

In some implementations, the plurality of side wall fillers may include carbon, oxygen, and silicon, and content of the oxygen is greater than a content of the carbon and a content of the silicon. In some implementations, the plurality of side wall fillers may further include at least one base filler that is free of the air pocket. In some implementations, the first side wall may include: a side wall low-density region including the at least one hollow filler; and a side wall high-density region in which the at least one base filler is disposed, the side wall high-density region having a higher density than the side wall low-density region. In some implementations, the side wall low-density region may be disposed between the first light emitting device and the side wall high-density region.

In some implementations, the light emitting apparatus may further comprise: a wavelength converter disposed on at least one surface of the first light emitting device and configured to convert a wavelength of light, wherein an upper end of the side wall low-density region is disposed under the wavelength converter. In some implementations, the light emitting apparatus may further comprise: a low-density region disposed between the first side wall and a side surface of the first light emitting device and configured to transmit light. In some implementations, the light emitting apparatus may further comprise: a high-density region disposed on an outer side of the first side wall and configured to absorb light.

In some implementations, the first light emitting device may include: a light emitting structure electrically connected to the base; and a light-transparent layer stacked above the light emitting structure, wherein the side wall low-density region is disposed between the light emitting structure and the side wall high-density region, and an upper end of the side wall low-density region is disposed below a lower surface of the light-transparent layer. In some implementations, the light emitting apparatus may further comprise a second light emitting device and a second side wall, wherein the first side wall extends upward from the base; and wherein the second side wall extends upward from the base to be disposed between the first light emitting device and the second light emitting device, and wherein each of the first side wall and the second side wall includes at least one of the side wall high-density region or the side wall low-density region.

In some implementations, the light emitting apparatus may further comprise a low-density region disposed between the second side wall and the first light emitting device and configured to refract light. In some implementations, the light emitting apparatus may further comprise a plurality of wavelength converters disposed on each of the first light emitting device and the second light emitting device and configured to convert wavelengths of light, wherein one region of the side wall low-density region of the second side wall is disposed between the plurality of wavelength converters, and another region of the side wall low-density region of the second side wall is disposed between the first light emitting device and the second light emitting device.

In some implementations, the light emitting apparatus may further comprise: a plurality of wavelength converters stacked on each of the first light emitting device and the second light emitting device and configured to convert wavelengths of light, wherein the side wall low-density region of the second side wall is disposed between the first light emitting device and the second light emitting device, and the side wall high-density region of the second side wall is disposed upward of the side wall low-density region, and is disposed between the plurality of wavelength converters. In some implementations, the light emitting apparatus may further comprise a wavelength converter disposed on the first light emitting device and the second light emitting device and configured to convert wavelengths of light, wherein the side wall high-density region and the side wall low-density region of the second side wall are disposed under the wavelength converter.

In some implementations, the side wall low-density region of the second side wall includes a plurality of side wall low-density regions, and the side wall high-density region of the second side wall is disposed between the plurality of side wall low-density regions of the second side wall. In some implementations, the side wall high-density region of the second side wall has a length in a horizontal direction that decreases toward a lower side thereof, and lower sides of the plurality of side wall low-density regions of the second side wall are connected to each other. In some implementations, the side wall low-density region of the first side wall is positioned between the side wall high-density region of the first side wall and a side surface of the first light emitting device.

In another aspect, a light emitting apparatus may be provided to comprise: a base; a side wall extending upward from the base; and a light emitting device disposed on the base and configured to generate light, wherein the side wall includes a plurality of side wall fillers configured to reflect or refract light, the plurality of side wall fillers includes a plurality of hollow fillers including an air pocket, and at least one of the plurality of hollow fillers is disposed on at least one of an inner surface or an outer surface of the side wall such that the air pocket is exposed to an outside. In some implementations, the light emitting apparatus may further comprise: a wavelength converter stacked on the light emitting device, wherein the wavelength converter covers the plurality of hollow fillers disposed on the inner surface of the side wall.

In another aspect, a light emitting apparatus may be provided to comprise: a base; a side wall disposed on the base; and a light emitting device disposed on the base and configured to generate light, wherein the side wall includes a plurality of side wall fillers configured to reflect or refract light, wherein the plurality of side wall fillers includes: a hollow filler including an air pocket; a base filler that is free of the air pocket; and a side wall matrix surrounding at least a region of the hollow filler or the base filler, wherein the side wall matrix, the hollow filler, and the base filler are mixed to have a volume ratio of a predetermined filler ratio, and wherein the side wall has a density lower than a density of a virtual density reference body in which the side wall matrix, the hollow filler, and the base filler are mixed to have the predetermined filler ratio.

A light emitting apparatus of one embodiment of the disclosed technology may have an effect of preventing optical interference by efficiently refracting light.

Embodiments of the disclosed technology can provide a light emitting apparatus having a stable structure without damage such as cracks even under heat generation or thermal stress.

Embodiments of the disclosed technology can provide a light emitting apparatus in which contrast is improved by minimizing optical interference between light emitting units.

Embodiments of the disclosed technology can provide a light emitting apparatus in which luminance is improved by adjusting the refraction direction.

Embodiments of the disclosed technology can provide a light emitting apparatus having high illuminance by increasing extraction efficiency.

### BRIEF DESCRIPTION OF DRAWINGS

FIG. 1 is a diagram illustrating an example of a light emitting apparatus according to a first embodiment of the disclosed technology.

FIG. 2 is a diagram illustrating an example of a side wall hollow filler of the light emitting apparatus in FIG. 1.

FIG. 3 is a diagram illustrating an example of a side wall base filler of the light emitting apparatus in FIG. 1.

FIG. 4 is a diagram illustrating a state in which a side wall of the light emitting apparatus in FIG. 1 includes a side wall low-density region and a side wall high-density region.

FIG. 5 is a diagram illustrating a state in which a low-density region of the light emitting apparatus in FIG. 1 is disposed between a light emitting device and the side wall.

FIG. 6 is a diagram illustrating a state in which a high-density region is disposed outside the side wall of the light emitting apparatus in FIG. 1.

FIG. 7 is a diagram illustrating an example of a light emitting apparatus according to a second embodiment of the disclosed technology.

FIG. 8 is a diagram illustrating a first example of a light emitting apparatus according to a third embodiment of the disclosed technology.

FIG. 9 is a diagram illustrating a second example of a light emitting apparatus according to the third embodiment of the disclosed technology.

FIG. 10 is a diagram illustrating a first example of a light emitting apparatus according to a fourth embodiment of the disclosed technology.

FIG. 11 is a diagram illustrating a second example of a light emitting apparatus according to the fourth embodiment of the disclosed technology.

FIG. 12 is a diagram illustrating an example of a light emitting apparatus according to a fifth embodiment of the disclosed technology.

FIG. 13 is a schematic rear view for describing a vehicle equipped with the light emitting apparatus according to one embodiment of the disclosed technology.

FIG. 14 is a schematic diagram for describing a light source apparatus equipped with the light emitting apparatus according to one embodiment of the disclosed technology.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a specific configuration of a light emitting apparatus 1 according to a first embodiment of the disclosed technology will be described with reference to the drawings.

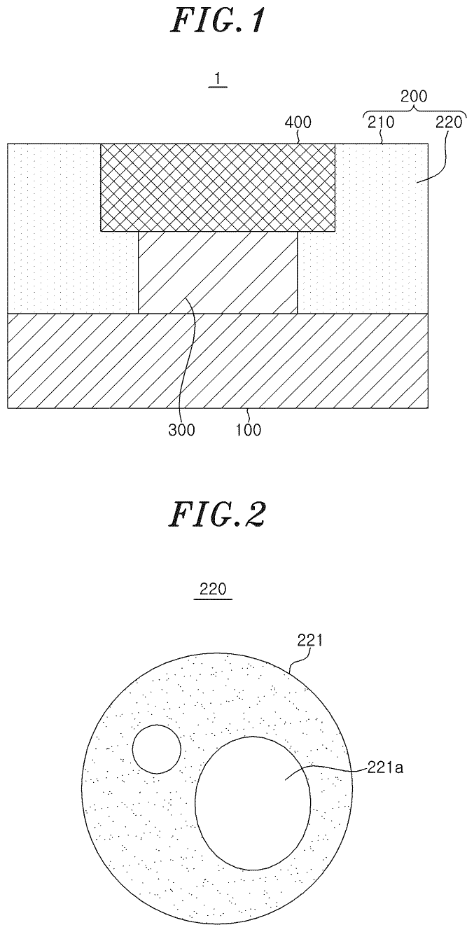

With reference to FIG. 1, the light emitting apparatus 1 according to the first embodiment of the disclosed technology may receive power from the outside and emit light. The light emitting apparatus 1 may include one or more of a base 100, a side wall 200, a light emitting device 300, a wavelength converter 400, a low-density region 500, and a high-density region 600.

The base 100 may support one or more of the side wall 200, the light emitting device 300, the low-density region 500, or the high-density region 600. For example, the base 100 may be a printed circuit board (PCB). In addition, the base 100 may include an alloy composed of or include one or more of Cu, Zn, Au, Ni, Al, Mg, Cd, Be, W, Mo, Si, Ag, or Fe, or the combination thereof. However, this is merely an example, and the base 100 may also include one or more of insulating materials such as FR1, CEM-1, FR-4, ceramic such as alumina or aluminum nitride, PMMA, or PC. Here, FR1 is a material in which copper foil and laminate paper are stacked, and CEM-1 is a material in which copper foil, glass fiber woven fabric, laminate paper, and glass fiber woven fabric are sequentially stacked. In addition, FR-4 is a material in which copper foil and glass fiber woven fabric or glass fiber fabric are stacked.

The side wall 200 may disposed on the base 100. To be more specific the side wall 200 may extend upward from the base 100. The side wall 200 may extend from an edge of the base 100 to provide an accommodation space in which the light emitting device 300 is accommodated. In other words, the side wall 200 may extend to surround at least a region of the light emitting device 300. A height of the side wall 200 may be formed to be higher than a height of the light emitting device 300. The side wall 200 may reflect light generated from the light emitting device 300. Such a side wall 200 may include a side wall matrix 210 and a plurality of side wall fillers 220. The side wall 200 and the base 100 may be formed of the same material. More specifically, the sidewall 200 and the base 100 may be integrally formed, but are not limited thereto, and may alternatively be formed separately.

The side wall matrix 210 may form at least a region of an exterior of the side wall 200, and may be formed to surround at least some of the plurality of side wall fillers 220. For example, the side wall matrix 210 may be composed of or include an insulating material such as silicone, epoxy mold compound (EMC), PMMA, or polycarbonate (PC).

The side wall filler 220 may be particles or pellets for reflecting or refracting light. The side wall filler 220 may reflect or refract light that is not reflected in the side wall 200 and flows into the interior. At least some of the outer surfaces of the side wall filler 220 may be surrounded by the side wall matrix 210, so that structural stability may be increased. The side wall filler 220 may be formed in plurality. The plurality of side wall fillers 220 may include one or more of carbon, oxygen, silicon, or aluminum. In addition, an air pocket may be formed such that content of oxygen is formed to be greater than content of carbon and silicon. Any one of the plurality of side wall fillers 220 may be configured as shown in Table 1 below. Table 1 is an example of testing data obtained using an energy-dispersive X-ray spectroscopy (EDX) and K refers to the K-line of the corresponding electron shell.

TABLE 1

| Element | Wt % | At % |
|---|---|---|
| CK | 23.63 | 33.37 |
| OK | 44.89 | 47.61 |
| SiK | 31.49 | 19.02 |

The side wall filler 220 is not limited to the above-mentioned configuration and may include various types of fillers. For example, the plurality of side wall fillers 220 may be fillers composed of or including at least one of silica (SiO₂), alumina (Al₂O₃), Titanium Dioxide (TiO₂), Barium Sulfate (BaSO₄) or others.

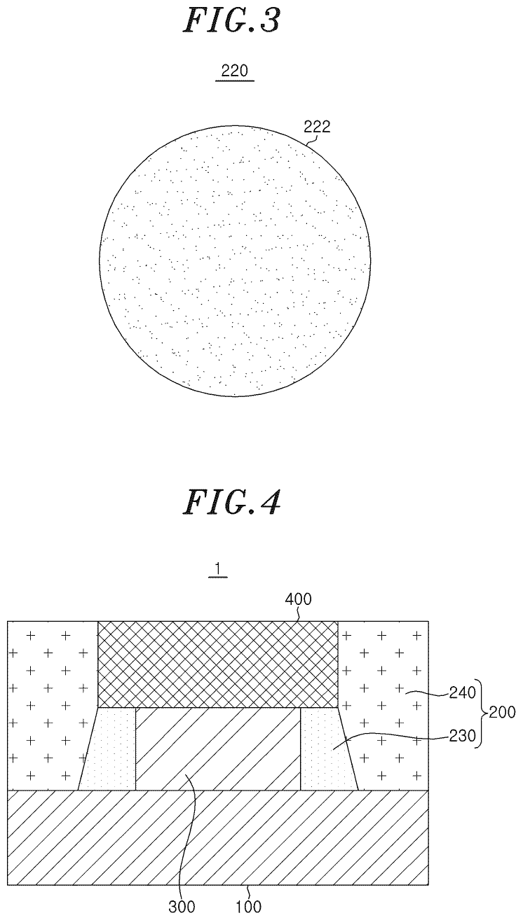

With further reference to FIGS. 2 and 3, the plurality of side wall fillers 220 may include at least one side wall hollow filler 221 and at least one side wall base filler 222.

The side wall hollow filler 221 may be a particle or pellet in which an air pocket 221a is formed inside. The air pocket 221a of the side wall hollow filler 221 may refract light. In other words, light may be refracted more in the side wall hollow filler 221 than in the side wall base filler 222. By the side wall hollow filler 221, light directed toward an outer surface of the side wall 200 may be refracted upward or toward an inner surface of the side wall 200, so that transmission through the outer surface of the side wall 200 may be prevented.

The side wall base filler 222 may be a particle or pellet in which the air pocket 221a is not formed inside. The side wall base filler 222 may refract or reflect light. A refractive index of the side wall base filler 222 may be formed greater than a refractive index of the side wall hollow filler 221. In addition, a refractive index of the side wall matrix 210 may be lower than the refractive index of the side wall base filler 222 or the side wall hollow filler 221. By forming the side wall 200 of materials having different refractive indices as described above, a light travel path may be diversified and contrast may be improved.

The side wall base filler 222 may have a different cross-sectional area from the side wall hollow filler 221. The side wall base filler 222 may have a smaller cross-sectional area than that of the side wall hollow filler 221. For example, the side wall base filler 222 may have a cross-sectional area that is 7% to 30% of the cross-sectional area of the side wall hollow filler 221. This may allow the content of the side wall base filler 222 to be easily increased.

Further, the side wall base filler 222 and the side wall hollow filler 221 may include materials having different refractive indices. The side wall base filler 222 may include materials with relatively high refractive indices, such as TiO₂ or BaSO₄. The side wall hollow filler 221 may include materials with relatively low refractive indices, such as SiO₂. By using materials with different refractive indices for the side wall base filler 222 and the side wall hollow filler 221, the design complexity of the optical refraction path can be reduced.

Further, the side wall base filler 222 and the side wall hollow filler 221 may include materials having different densities. The side wall base filler 222 may include materials with relatively high density, such as TiO₂ or BaSO₄. The side wall hollow filler 221 may include materials with relatively low density, such as SiO₂. By incorporating materials of relatively high and low densities through the side wall base filler 222 and the side wall hollow filler 221, the light emitting apparatus 1 can achieve adjustable thermal conductivity and maintain structural stability without damage, such as cracking, under thermal stress.

The side wall matrix 210, the side wall hollow filler 221, and the side wall base filler 222 may be mixed to have a volume ratio of a predetermined filler ratio. The side wall 200 may have a density lower than a density of a virtual density reference body in which the side wall matrix 210, the side wall hollow filler 221, and the side wall base filler 222 are mixed to have a filler ratio. For example, when including the side wall matrix 210, the side wall hollow filler 221, and the side wall base filler 222, a density of the side wall 200 may be formed smaller than when including only the side wall matrix 210 and the side wall base filler 222. The side wall matrix 210, the side wall hollow filler 221, and the side wall base filler 222 enable the light emitting apparatus 1 to maintain structural stability without failure, such as cracking, even under mechanical stress.

With further reference to FIG. 4, at least one of the side wall hollow filler 221 or the side wall base filler 222 may be included more than the other in the side wall 200. Such a side wall may include one or more of a side wall low-density region 230 and a side wall high-density region 240.

The side wall low-density region 230 may be a region in which the side wall hollow filler 221 is disposed more than the side wall base filler 222. In the side wall low-density region 230, more air pockets 221a may be included than in the side wall high-density region 240. The side wall low-density region 230 may have a refractive index lower than a refractive index of the side wall high-density region 240. Refractive index adjustment through the side wall hollow filler 221 can reduce thermal stress and simplify the design of optical path control.

The side wall high-density region 240 may be a region in which the side wall base filler 222 is disposed more than the side wall hollow filler 221. A density of the side wall high-density region 240 may be greater than a density of the side wall low-density region 230. In addition, the side wall high-density region 240 may absorb more light than the side wall low-density region 230. Such a side wall high-density region 240 may reduce interference between light. The content of the side wall base filler 222 disposed in the side wall high-density region 240 may be 2.5 to 5 times higher by weight percent (Wt %) than the content of the side wall base filler 222 disposed in the side wall low-density region 230. Alternatively, the content of the side wall base filler 222 in the side wall high-density region 240 may be 3.5 to 7.5 times higher by atomic percent (At %) than that in the side wall low-density region 230. If the content of the side wall base filler 222 in the side wall high-density region 240 is lower than the above range, the reflective effect of the high-density region may be reduced. On the other hand, if the content of the side wall base filler 222 in the side wall high-density region 240 is higher than the above range, it may cause processability issues, making it necessary to appropriately control the amount of the side wall base filler 222.

In a first example, the side wall 200 may include only the side wall low-density region 230. In other words, the side wall low-density region 230 may be disposed at at least one side surface region of the light emitting device 300 and at least one region of the wavelength converter 400. The side wall 200 may enhance luminance by reflecting light emitted from at least one side surface of the light emitting device 300 upward via the side wall low-density region 230.

In a second example, the side wall 200 may include the side wall low-density region 230 and the side wall high-density region 240. The side wall low-density region 230 may be disposed between a side surface of the light emitting device 300 and the side wall high-density region 240. Light emitted from the side surface of the light emitting device 300 may undergo double reflection by the side wall low-density region 230 and the side wall high-density region 240, which can reduce side-emitted light and suppress optical interference. The side wall low-density region 230 may be formed smaller than a size of the side wall high-density region 240. In addition, an upper surface of the side wall low-density region 230 may be disposed below a lower surface of the wavelength converter 400. An upper side of the side wall high-density region 240 may be connected to the wavelength converter 400. Through this, by adjusting the emission path of light toward an upper surface of the wavelength converter 400, the contrast of the light emitting apparatus may be improved.

The light emitting device 300 may generate light. The light emitting device 300 may be electrically connected to an electric circuit of the base 100, and may generate light by receiving electricity from the outside through the electric circuit. The light emitting device 300 may include a first conductive-type semiconductor layer, an active layer, and a second conductive-type semiconductor layer disposed on at least one region of a device substrate. The first conductive-type semiconductor layer may include a phosphide-based or nitride-based semiconductor, such as (Al, Ga, In) P or (Al, Ga, In) N. The first conductive-type semiconductor layer may be doped as n-type, and may include at least one impurity such as Si, C, Ge, Sn, Te, or Pb. However, the first conductive-type semiconductor layer is not limited thereto and may also be doped as p-type by including a p-type dopant. The active layer is a light emitting layer formed between the first conductive-type semiconductor layer and the second conductive-type semiconductor layer, and may include a phosphide-based or nitride-based semiconductor such as (Al, Ga, In) P or (Al, Ga, In) N, and may include a quantum well structure (QW) including two barrier layers and at least one well layer. In addition, the active layer may adjust a wavelength of emitted light by adjusting a composition ratio forming the well layer. The second conductive-type semiconductor layer may be a semiconductor layer formed on the active layer. The second conductive-type semiconductor layer may include a phosphide-based or nitride-based semiconductor such as (Al, Ga, In) P or (Al, Ga, In) N, and the second conductive-type semiconductor layer may be doped with a conductive type opposite to that of the first conductive-type semiconductor layer. For example, the second conductive-type semiconductor layer may be doped with p-type by including an impurity such as Mg. The second conductive-type semiconductor layer may be formed as a single layer having a composition such as p-GaN, but is not limited thereto, and may further include an AlGaN layer inside. The light emitting device 300 may include a lower contact layer, an insulating layer, a P-electrode pad, and an N-electrode pad. In addition, the light emitting device 300 may be configured as any one of a flip-chip, in which the P-electrode pad and the N-electrode pad are disposed in a lower region of a device substrate, a lateral chip in which a semiconductor layer is formed in an upper region of the device substrate, and P-electrode pad and N-electrode pad are disposed in an upper region of the semiconductor layer on an upper side of the device substrate, and a vertical chip, in which either the P-electrode pad or the N-electrode pad is disposed in a lower region of the device substrate.

The wavelength converter 400 may be disposed in an accommodation space of the side wall 200, may cover at least one region of the light emitting device 300, and may improve light extraction efficiency of the light emitting device 300. In addition, the wavelength converter 400 may encapsulate the light emitting device 300, and may refract light emitted from the light emitting device 300. In addition, the wavelength converter 400 may be a light-transmissive transparent molding for transmitting light emitted from the light emitting device 300. For example, the wavelength converter 400 may be formed of a resin including at least one of a silicone-based, an epoxy-based, a polymethyl methacrylate (PMMA)-based, a polyethylene (PE)-based, and a polystyrene (PS)-based material, a ceramic element such as Al₂O₃, or a glass element such as SiO₂. In addition, the wavelength converter 400 may be formed of a fluorine resin for improving light efficiency of light emitted from a plurality of light emitting devices 300.

The wavelength converter 400 may include a wavelength conversion material such as a phosphor, quantum dot (QD), or organic dye that is capable of converting a wavelength of light emitted from the light emitting device 300. For example, the wavelength conversion material may include a fluorescent material capable of emitting at least one of red light, blue light, or green light. The wavelength converter 400 may include at least one of a LuAG-based, a YAG-based, a beta-SiAlON-based, a nitride-based, a silicate-based, a halophosphate-based, or an oxynitride-based material. In addition, the wavelength converter 400 may emit light having a peak wavelength in a red light band. For example, a second wavelength conversion material 118 may include at least one of a nitride-based material such as CASN, CASON, and SCASN, a silicate-based, a sulfide-based, or a fluoride-based material. The wavelength converter 400 may include at least one same element as the side wall filler or the side wall hollow filler of the side wall 200, and through this, may strengthen adhesion and implement a light emitting apparatus having a stable structure.

In addition, the wavelength converter 400 may include a light diffusion material capable of diffusing light emitted from the light emitting device 300. For example, the light diffusion material may include at least one of TiO₂, BaO, SiO₂, MgO, or Y₂O₃, which is capable of scattering light. The wavelength converter 400 may contain some of the same materials as the fillers of the side wall 200.

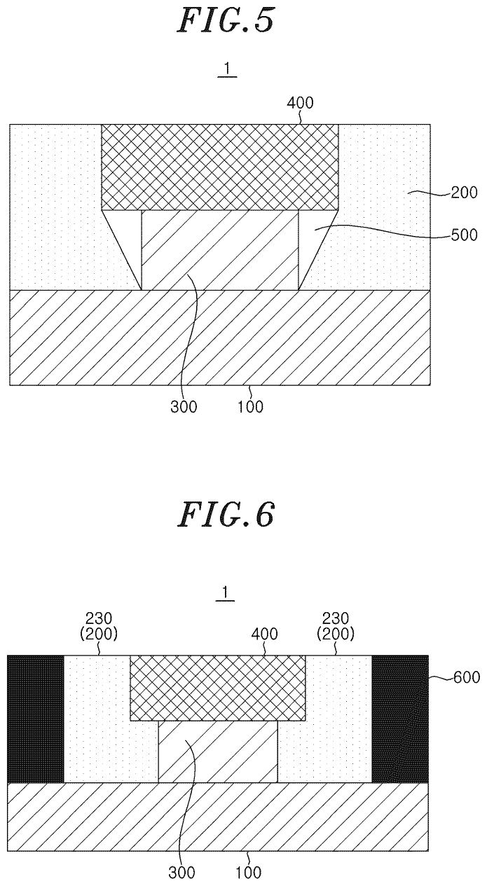

With further reference to FIG. 5, the low-density region 500 may be disposed between the side wall 200 and the light emitting device 300 so that light generated from the light emitting device 300 is transmitted. An upper surface of the low-density region 500 may be disposed below a lower surface of the wavelength converter 400. Such a low-density region 500 may allow light to pass therethrough. The interior of the low-density region 500 may not include any filler. Since light can be reflected at the interface between the side wall 200 and the low-density region 500, the contrast can be increased. In addition, the low-density region 500 may include a plurality of fillers. In addition, a plurality of fillers may also be included inside the low-density region 500. The filler disposed inside the low-density region 500 may be referred to as a low-density region filler. In other words, the low-density region 500 may include at least one of a low-density region base filler in which an air pocket is not formed inside, or a low-density region hollow filler in which an air pocket is formed inside. The amount of filler in the low-density region 500 may be lower than the amount of filler in the side wall 200.

With further reference to FIG. 6, the high-density region 600 may be disposed on an outer side of the side wall 200 and may have high density by including a large amount of fillers. The high-density region 600 may absorb light. The high-density region 600 may be composed of or include resin and pigment (C) or others. In addition, a plurality of fillers may also be included inside the high-density region 600. The filler disposed inside the high-density region 600 may be referred to as a high-density region filler. In other words, the high-density region 600 may include at least one of a high-density region base filler in which an air pocket is not formed inside, or a high-density region hollow filler in which an air pocket is formed inside. For example, the high-density region 600 may include only the high-density region base filler. The high-density region 600 may include a pigment containing carbon (C) to increase light blocking efficiency. Therefore, the carbon content of the high-density region 600 may be higher than that of the side wall 200. The carbon content of the high-density region 600 may be 2 to 4 times higher by weight percent (Wt %) compared to the carbon content of the side wall 200. Alternatively, the carbon content of the high-density region 600 may be 2 to 4 times higher by atomic percent (At %) than that of the side wall 200. The high carbon content in the high-density region 600 can block side-emitted light and thus increase contrast.

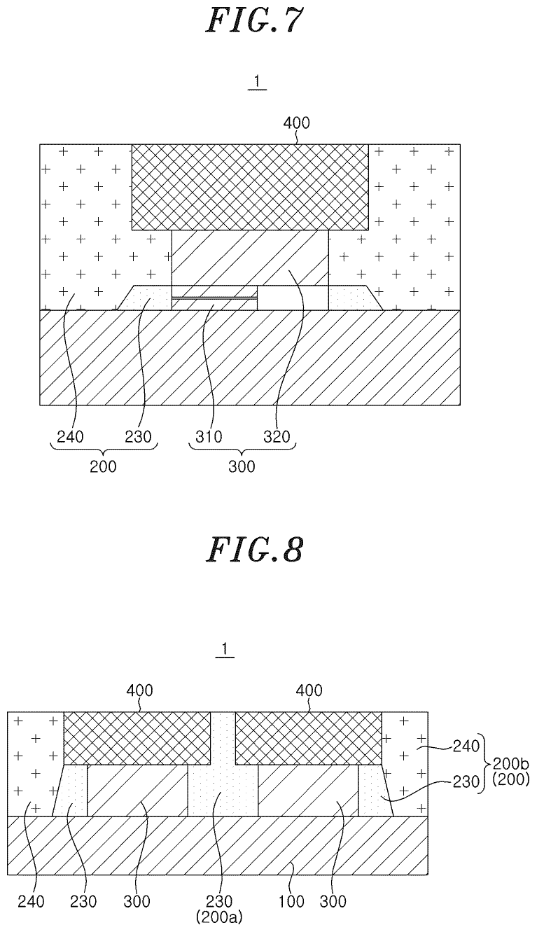

Hereinafter, with reference to FIG. 7, a light emitting apparatus 1 according to a second embodiment of the disclosed technology will be described. In describing the second embodiment, since the light emitting device 300 has a difference in that it may include a light emitting structure 310 and a light-transparent layer 320, such a difference will mainly be described.

The light emitting structure 310 may generate light. A total thickness of the light emitting structure 310 may be in a range of 1 μm to 10 μm. The light emitting structure 310 may include a first conductive-type semiconductor layer, an active layer, and a second conductive-type semiconductor layer.

The first conductive-type semiconductor layer may be electrically connected to the base 100. The first conductive-type semiconductor layer may include n-type impurities (e.g., Si, Ge, Sn), and in this case, the first conductive-type semiconductor layer may be an n-type semiconductor layer. However, this is merely an example, and the first conductive-type semiconductor layer may also include p-type impurities.

The active layer may be stacked on the first conductive-type semiconductor layer. In other words, the active layer may be positioned between the first conductive-type semiconductor layer and the second conductive-type semiconductor layer.

The second conductive-type semiconductor layer may be stacked on the active layer, and may be electrically connected to the base 100. The second conductive-type semiconductor layer may include p-type impurities (e.g., Mg, Sr, Ba). In this case, the second conductive-type semiconductor layer may be a p-type semiconductor layer. However, this is merely an example, and the second conductive-type semiconductor layer may also include p-type impurities.

The light-transparent layer 320 may be stacked on the light emitting structure 310. In other words, the light-transparent layer 320 may be stacked on the second conductive-type semiconductor layer. The light-transparent layer 320 may be an insulating or conductive substrate for growing the first conductive-type semiconductor layer, the active layer, and the second conductive-type semiconductor layer. As an example, the light-transparent layer 320 may include at least one of a sapphire substrate, a silicon carbide substrate, a silicon substrate, a gallium nitride substrate, or an aluminum nitride substrate.

The side wall low-density region 230 may be disposed between the light emitting structure 310 and the side wall high-density region 240, and an upper end thereof may be disposed below a lower surface of the light-transparent layer 320. In other words, the side wall low-density region 230 may be connected to a side surface of the light emitting structure 310. The side wall high-density region 240 may be connected to the light emitting structure 310 and the wavelength converter 400.

Hereinafter, a light emitting apparatus 1 according to a third embodiment of the disclosed technology will be described. In the third embodiment, the side wall 200, the light emitting device 300, and the wavelength converter 400 are formed in plurality, which are different from other embodiments. The third embodiment will be described by focusing on such differences.

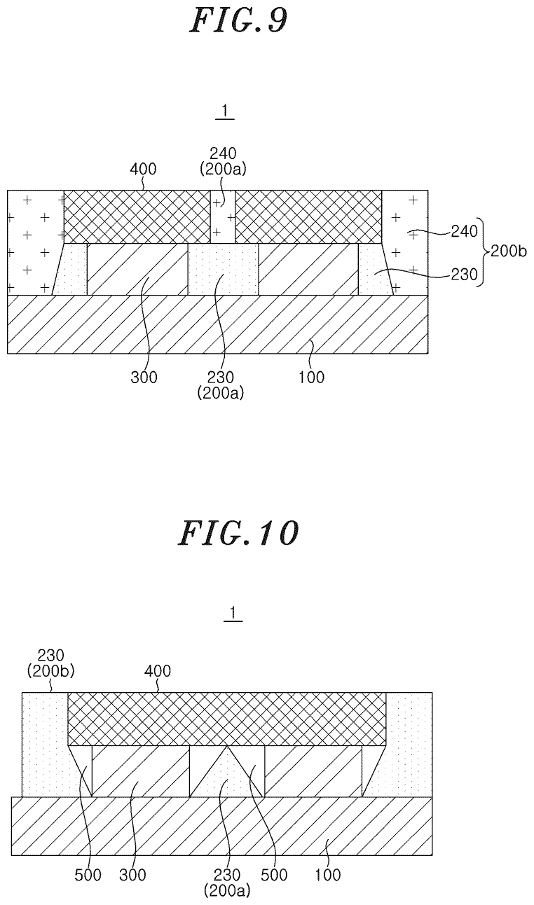

With reference to FIGS. 8 and 9, the plurality of side walls 200 may include an inner wall 200a and an outer wall 200b. In the example, the outer wall 200b may correspond to the side wall as described in the previous embodiments and the inner wall 200a may correspond to an additional side wall. Hereinafter, the side wall low-density region 230 and the side wall high-density region 240 included in the inner wall 200a are referred to as inner wall low-density region 230 and inner wall high-density region 240, respectively. In addition, the side wall low-density region 230 and the side wall high-density region 240 included in the outer wall 200b are referred to as outer wall low-density region 230 and outer wall high-density region 240, respectively.

The inner wall 200a may extend upward from the base 100 so as to be disposed between the plurality of light emitting devices 300. An upper side of the inner wall 200a may be positioned between the plurality of wavelength converters 400. A lower side of the inner wall 200a may be positioned between the plurality of light emitting devices 300. The inner wall 200a may include at least one of the inner wall low-density region 230 or the inner wall high-density region 240.

In a first example, the inner wall 200a may include only the inner wall low-density region 230. In other words, an upper side of the inner wall low-density region 230 of the inner wall 200a may be disposed between the plurality of wavelength converters 400, and may be connected to side surfaces of the plurality of wavelength converters 400. In addition, a lower side of the inner wall low-density region 230 of the inner wall 200a may be disposed between the plurality of light emitting devices 300, and may be connected to side surfaces of the plurality of light emitting devices 300. The inner wall low-density region 230 can reduce the mixing of light between the plurality of wavelength converters 400, thereby improving contrast.

In a second example, the inner wall 200a may include the inner wall low-density region 230 and the inner wall high-density region 240. The inner wall low-density region 230 of the inner wall 200a may be disposed between the plurality of light emitting devices 300, and may be connected to side surfaces of the plurality of light emitting devices 300. The inner wall high-density region 240 of the inner wall 200a may be disposed on an upper side of the inner wall low-density region 230, and may be disposed between the plurality of wavelength converters 400, and may be connected to side surfaces of the plurality of wavelength converters 400. In addition, an upper surface of the inner wall low-density region 230 may be disposed below a lower surface of the wavelength converter 400, so that light may be refracted toward the wavelength converter 400, thereby increasing light extraction efficiency. A width of the inner wall high-density region 240 connected to the side surface of the wavelength converter 400 may be smaller than a width of the inner wall low-density region 230 located beneath the wavelength converter 400. The inner wall low-density region 230 beneath the wavelength converter 400 may be disposed on the side surface of the light emitting device 300. The inner wall low-density region 230 can refract a portion of the side-emitted light from the light emitting device 300 toward the wavelength converter 400, thereby improving optical efficiency.

The outer wall 200b may extend upward from an edge of the base 100. In other words, the plurality of light emitting devices 300 and the inner wall 200a may be disposed inside the outer wall 200b. The outer wall 200b may include one or more of the outer wall low-density region 230 or the outer wall high-density region 240.

In a first example, the outer wall 200b may include only the outer wall low-density region 230. The outer wall low-density region 230 may be connected to the plurality of wavelength converters 400 and the plurality of light emitting devices 300. The outer wall low-density region 230 can refract light emitted from the side surface of the light emitting device 300 toward the wavelength converter 400, thereby improving optical efficiency.

In a second example, the outer wall 200b may include the outer wall low-density region 230 and the outer wall high-density region 240. The outer wall low-density region 230 may be disposed between the outer wall high-density region 240 and a side surface of the light emitting device 300. In addition, an upper surface of the outer wall low-density region 230 may be disposed below a lower surface of the wavelength converter 400. The outer wall 200b can refract light emitted from the side surface of the light emitting device 300 toward the wavelength converter 400, thereby enhancing optical efficiency. The outer wall high-density region 240 may be formed larger than the outer wall low-density region 230, may be connected to a side surface of the wavelength converter 400. A height of the outer wall high-density region 240 may be 1.6 to 2 times greater than a height of the outer wall low-density region 230. The outer wall high-density region 240 can protect the light emitting device 300 from external impact.

Hereinafter, a light emitting apparatus 1 according to a fourth embodiment of the disclosed technology will be described. In describing the fourth embodiment, since there is a difference in that the wavelength converter 400 is stacked on the plurality of light emitting devices 300, such a difference will mainly be described.

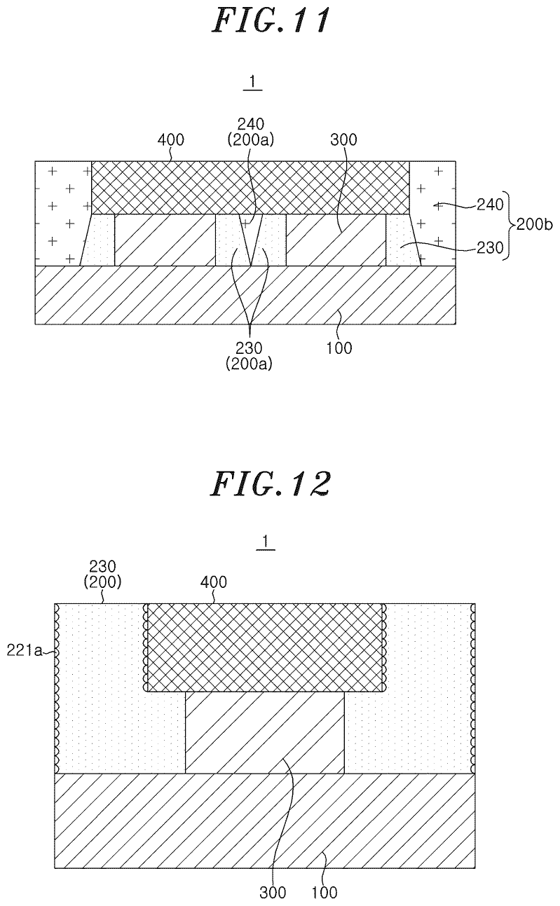

With reference to FIGS. 10 and 11, the wavelength converter 400 may be stacked on the plurality of light emitting devices 300, and may cover the plurality of light emitting devices 300. An upper surface of the inner wall 200a may be disposed below a lower surface of the wavelength converter 400. Through this, the wavelength converter 400 may be supported, and structural stability may be improved.

In a first example, the inner wall 200a may be formed such that a length in a horizontal direction becomes smaller toward an upper side thereof. The inner wall 200a may include only the inner wall low-density region 230, but is not limited thereto. In addition, the low-density region 500 may be disposed between the inner wall 200a and the light emitting device 300, and between the outer wall 200b and the light emitting device 300, respectively. The inner wall 200a can refract side-emitted light toward the wavelength converter 400, thereby increasing light extraction efficiency. A maximum height of the low-density region 500 may be greater than a height of the highest point of the inner wall 200a. Due to the low-density region 500 and the inner wall 200a, more light may be refracted toward the wavelength converter 400.

In a second example, the inner wall 200a may include the inner wall low-density region 230 and the inner wall high-density region 240. The inner wall low-density region 230 and the inner wall high-density region 240 of the inner wall 200a may be disposed below the wavelength converter 400. Such inner wall low-density regions 230 may be formed in plurality. The inner wall high-density region 240 may be disposed between the plurality of inner wall low-density regions 230. The inner wall high-density region 240 may refract light increasingly toward a center, which can enhance contrast. The inner wall high-density region 240 may be formed such that a length in a horizontal direction decreases toward a lower side thereof. As a result of the inner wall high-density region 240, side-emitted light from the light-emitting element 300 may be increasingly refracted upward, which can reduce cross-talk between the adjacent light emitting devices 300. In addition, lower sides of the plurality of inner wall low-density regions 230 may be connected to each other. Through this, side light may be refracted toward the wavelength converter, thereby increasing light extraction efficiency.

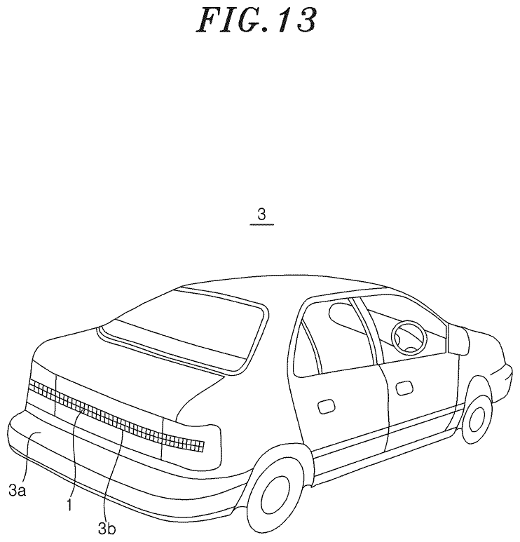

Hereinafter, with reference to FIG. 12, a light emitting apparatus 1 according to a fifth embodiment of the disclosed technology will be described. In describing the fifth embodiment, since there is a difference in that the side wall hollow filler 221 is disposed on an outer surface of the side wall 200 so that the air pocket 221a is exposed to the outside, such a difference will mainly be described.

As the side wall 200 is diced, the side wall hollow filler 221 may be cut so that the air pocket 221a is exposed to the outside. In other words, the side wall hollow filler 221 may be disposed on at least one of an inner surface or an outer surface of the side wall 200 so that the air pocket 221a is exposed to the outside. In addition, the air pocket 221a may be formed on at least one of the inner surface or the outer surface of the side wall 200, and may form a groove on at least one of the inner surface or the outer surface of the side wall 200. The groove can increase the surface roughness of the side wall 200, diversify the light travel path, reduce side-emitted light, and thereby enhance contrast. The side wall hollow filler 221, disposed on the inner surface of the side wall 200, may be covered by the wavelength converter 400. The side wall hollow filler 221 can refract side-emitted light from the wavelength converter 400, thereby reducing side-emitted light and improving contrast.

FIG. 13 is a schematic perspective view for describing a vehicle 3 equipped with a light emitting apparatus 1 according to one embodiment of the present disclosure.

With reference to FIG. 13, the vehicle 3 may include a vehicle main body 3a and a vehicle luminaire 3b mounted on the vehicle main body 3a. The vehicle main body 3a may be a vehicle body forming the exterior of the vehicle. The vehicle luminaire 3b may be a rear lamp, a headlamp, a rear lamp, a tail lamp, or others. In addition, the vehicle luminaire 3b may emit light of the red color, light of the yellow color, or light of the white color. The vehicle luminaire 3b may have a plurality of light emitting apparatuses 1 or a plurality of light emitting devices 300 mounted therein, and each of the light emitting apparatuses 1 or the plurality of light emitting devices 300 may be driven individually by respective regions. Through this, information such as a stop signal or text may be displayed to the outside. The light emitting apparatus 1 according to the present embodiment may reduce optical interference between a plurality of light emitting apparatuses 1 or a plurality of light emitting devices 300, may increase contrast, may exhibit clear brightness contrast, and may display a clearer image. In addition, a clear brightness contrast between a driving region and a non-driving region may enable implementation of a clear cut-off line in a headlamp or others, thereby reducing glare for an oncoming vehicle driver.

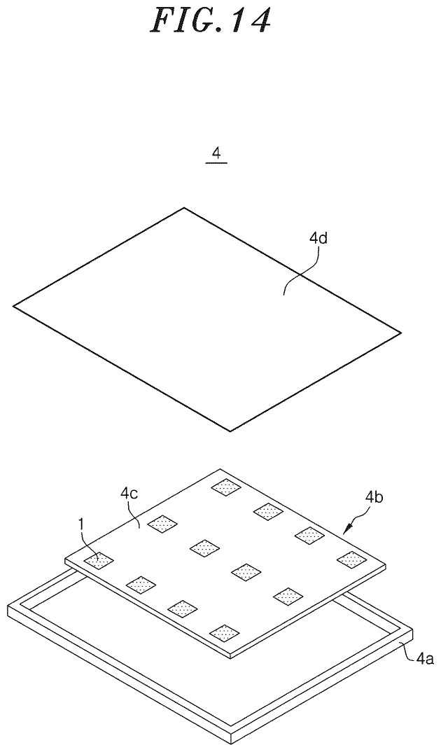

FIG. 14 is a schematic diagram for describing a light source apparatus 4 equipped with the light emitting apparatus 1 according to an embodiment of the present disclosure.

With reference to FIG. 14, the light source apparatus 4 may include a light source main body 4a and a surface light source 4b mounted on the light source main body 4a. The light source apparatus 4 may be a display device, a lighting device, or others. The light source main body 4a may include a high-density material having high thermal conductivity, and may improve reliability of the light source apparatus 4. The plurality of light emitting apparatuses 1 or the plurality of light emitting devices 300 may be mounted on a substrate 4c including electrical wiring of the surface light source 4b, and each of the light emitting apparatuses 1 or the plurality of light emitting devices 300 may individually drive by respective regions to control luminance or to control a light emission region. In addition, on an upper surface of the surface light source 4b, an optical sheet 4d including at least one of a diffusion sheet, a polarization sheet, or a color conversion sheet for diffusing light may be disposed. The light source apparatus 4 according to the present embodiment may reduce optical interference between the plurality of light emitting apparatuses 1 or the plurality of light emitting devices 300, minimize interference between driving regions, and have distinct brightness contrast. In addition, through this, when the light source apparatus 4 is applied to a display device, it is possible to implement a high-quality display device having distinct contrast.

The examples of the present disclosure have been described above as specific embodiments, but these are only examples, and the present disclosure is not limited thereto. Variations, modifications, and enhancements to the described examples and implementations and other implementations can be made based on what is disclosed.

1. A light emitting apparatus, comprising:
a base;
a first side wall disposed on the base; and
a first light emitting device disposed on the base and configured to generate light,
wherein the first side wall includes a plurality of side wall fillers configured to reflect or refract light, and
wherein the plurality of side wall fillers includes at least one hollow filler including an air pocket.

2. The light emitting apparatus of claim 1, wherein the plurality of side wall fillers includes carbon, oxygen, and silicon, and
content of the oxygen is greater than a content of the carbon and a content of the silicon.

3. The light emitting apparatus of claim 1, wherein the plurality of side wall fillers further includes at least one base filler that is free of the air pocket.

4. The light emitting apparatus of claim 3, wherein the first side wall includes:
a side wall low-density region including the at least one hollow filler; and
a side wall high-density region in which the at least one base filler is disposed, the side wall high-density region having a higher density than the side wall low-density region.

5. The light emitting apparatus of claim 4, wherein the side wall low-density region is disposed between the first light emitting device and the side wall high-density region.

6. The light emitting apparatus of claim 4, further comprising:
a wavelength converter disposed on at least one surface of the first light emitting device and configured to convert a wavelength of light, wherein an upper end of the side wall low-density region is disposed under the wavelength converter.

7. The light emitting apparatus of claim 2, further comprising:
a low-density region disposed between the first side wall and a side surface of the first light emitting device and configured to transmit light.

8. The light emitting apparatus of claim 2, further comprising:
a high-density region disposed on an outer side of the first side wall and configured to absorb light.

9. The light emitting apparatus of claim 4, wherein the first light emitting device includes:
a light emitting structure electrically connected to the base; and
a light-transparent layer stacked above the light emitting structure,
wherein the side wall low-density region is disposed between the light emitting structure and the side wall high-density region, and an upper end of the side wall low-density region is disposed below a lower surface of the light-transparent layer.

10. The light emitting apparatus of claim 4, further comprising: a second light emitting device and a second side wall,
wherein the first side wall extends upward from the base; and
wherein the second side wall extends upward from the base to be disposed between the first light emitting device and the second light emitting device, and
wherein each of the first side wall and the second side wall includes at least one of the side wall high-density region or the side wall low-density region.

11. The light emitting apparatus of claim 10, further comprising:
a low-density region disposed between the second side wall and the first light emitting device and configured to refract light.

12. The light emitting apparatus of claim 10, further comprising:
a plurality of wavelength converters disposed on each of the first light emitting device and the second light emitting device and configured to convert wavelengths of light,
wherein one region of the side wall low-density region of the second side wall is disposed between the plurality of wavelength converters, and
another region of the side wall low-density region of the second side wall is disposed between the first light emitting device and the second light emitting device.

13. The light emitting apparatus of claim 10, further comprising:
a plurality of wavelength converters stacked on each of the first light emitting device and the second light emitting device and configured to convert wavelengths of light,
wherein the side wall low-density region of the second side wall is disposed between the first light emitting device and the second light emitting device, and
the side wall high-density region of the second side wall is disposed upward of the side wall low-density region, and is disposed between the plurality of wavelength converters.

14. The light emitting apparatus of claim 10, further comprising:
a wavelength converter disposed on the first light emitting device and the second light emitting device and configured to convert wavelengths of light,
wherein the side wall high-density region and the side wall low-density region of the second side wall are disposed under the wavelength converter.

15. The light emitting apparatus of claim 14, wherein the side wall low-density region of the second side wall includes a plurality of side wall low-density regions, and
the side wall high-density region of the second side wall is disposed between the plurality of side wall low-density regions of the second side wall.

16. The light emitting apparatus of claim 15, wherein the side wall high-density region of the second side wall has a length in a horizontal direction that decreases toward a lower side thereof, and lower sides of the plurality of side wall low-density regions of the second side wall are connected to each other.

17. The light emitting apparatus of claim 10, wherein the side wall low-density region of the first side wall is positioned between the side wall high-density region of the first side wall and a side surface of the first light emitting device.

18. A light emitting apparatus, comprising:
a base;
a side wall extending upward from the base; and
a light emitting device disposed on the base and configured to generate light,
wherein the side wall includes a plurality of side wall fillers configured to reflect or refract light,
the plurality of side wall fillers includes a plurality of hollow fillers including an air pocket, and
at least one of the plurality of hollow fillers is disposed on at least one of an inner surface or an outer surface of the side wall such that the air pocket is exposed to an outside.

19. The light emitting apparatus of claim 18, further comprising:
a wavelength converter stacked on the light emitting device, wherein the wavelength converter covers the plurality of hollow fillers disposed on the inner surface of the side wall.

20. A light emitting apparatus, comprising:
a base;
a side wall disposed on the base; and
a light emitting device disposed on the base and configured to generate light,
wherein the side wall includes a plurality of side wall fillers configured to reflect or refract light,
wherein the plurality of side wall fillers includes:
a hollow filler including an air pocket;
a base filler that is free of the air pocket; and
a side wall matrix surrounding at least a region of the hollow filler or the base filler,
wherein the side wall matrix, the hollow filler, and the base filler are mixed to have a volume ratio of a predetermined filler ratio, and
wherein the side wall has a density lower than a density of a virtual density reference body in which the side wall matrix, the hollow filler, and the base filler are mixed to have the predetermined filler ratio.
